(19) United States
(12) Patent Application Publication
(10) Pub. No.: US 2022/0416152 A1
(43) Pub. Date: Dec. 29, 2022

(54) BARIUM TITANATE FIBER, RESIN COMPOSITION CONTAINING SAME, POLYMER COMPOSITE PIEZOELECTRIC BODY, PIEZOELECTRIC ELEMENT, METHOD FOR PRODUCING BARIUM TITANATE FIBER, AND METHOD FOR PRODUCING POLYMER COMPOSITE PIEZOELECTRIC BODY

(71) Applicant: JNC CORPORATION, Tokyo (JP)

(72) Inventors: You UMEBAYASHI, Tokyo (JP); Miwako NISHIMURA, Tokyo (JP)

(73) Assignee: JNC CORPORATION, Tokyo (JP)

(21) Appl. No.: 17/629,399

(22) PCT Filed: Jul. 27, 2020
(86) PCT No.: PCT/JP2020/028705

§ 371 Date: Jan. 23, 2022

(30) Foreign Application Priority Data
Aug. 8, 2019 (JP) 2019-146507
Jul. 20, 2020 (JP) 2020-123452

(51) Int. Cl. H01L 41/18; C01G 23/00; C08J 5/04; C08J 3/215; C09D 11/52; C09D 11/037; C09D 11/106; D01F 9/08; D01D 5/00

(52) U.S. Cl. CPC H01L 41/183; C01G 23/006; C08J 5/0405; C08J 3/215; C09D 11/52; C09D 11/037; C09D 11/106; D01F 9/08; D01D 5/0038; C08J 2327/16; D10B 2101/08; H01L 41/37

(57) ABSTRACT

A barium titanate fiber is useful as a filler for a polymer composite piezoelectric body, a polymer composite piezoelectric body has high piezoelectric properties, and a piezoelectric element utilizes the polymer composite piezoelectric body. In the barium titanate fiber, the molar ratio of barium atoms to titanium atoms (Ba/Ti ratio) falls within the range of 1.01 to 1.04. The polymer composite piezoelectric body includes a resin composition containing the barium titanate fiber and a polymer. The piezoelectric element including an electrically conductive layer on one surface or both surfaces of the polymer composite piezoelectric body.

### TECHNICAL FIELD

The present invention relates to a barium titanate fiber, a resin composition containing the same, a varnish, a polymer composite piezoelectric body, and a piezoelectric element. The present invention also relates to a method for producing these.

### BACKGROUND ART

Piezoelectric ceramics, such as barium titanate and lead zirconate titanate, have excellent piezoelectric and dielectric properties and have been applied to sensors, power generation elements, actuators, acoustic equipment, capacitors, and the like. Although piezoelectric ceramics have excellent piezoelectric and dielectric properties and high heat resistance, the piezoelectric ceramics are hard and brittle, and thus there have been problems that the flexibility was poor and it was difficult to increase the area and processability. In order to solve these problems, a polymer composite piezoelectric body in which a polymer is filled with a piezoelectric ceramic powder as a filler, have been used. Such polymer composite piezoelectric bodies are attracting attention as materials that combine the excellent flexibility and processability of polymers with the excellent piezoelectric and dielectric properties of piezoelectric ceramics, and by changing the type of polymer and the composition, shape, and compounding ratio of piezoelectric ceramics, it is possible to design materials according to the purpose.

Patent Literature 1 describes a highly dielectric film containing a vinylidene fluoride polymer, barium titanate oxide particles and/or lead zirconate titanate oxide particles, and an affinity enhancer. However, no investigation has been conducted regarding piezoelectricity.

Meanwhile, investigation has been conducted focusing on a Ba/Ti molar ratio as a method for improving the properties of barium titanate. Patent Literature 2 describes a raw material powder for a barium titanate sintered body having a Ba/Ti molar ratio of 1.01 to 1.18, which is sintered at a temperature of 950 to 1100° C. However, Patent Literature 2 describes a powder for a sintered body, which is not supposed to be filled into a polymer, and does not address piezoelectricity. In addition, Patent Literatures describes a highly dielectric elastomer composition containing, based on the total weight, 5 to 80% by weight of composite fibers integrated in a state of a titanate metal salt fibrous material represented by the general formula MO.TiO₂ and/or amorphous titanium oxide wrapping the titanate metal salt, that is, composite fibers having a molar ratio of metal M to Ti in the range of 1:1.005 to 1.5, in the elastomer matrix. However, it is still desired to develop a composite piezoelectric body that can exhibit excellent piezoelectric and dielectric properties attributed to titanate metal salts, in addition to the excellent flexibility and processability attributed to polymers.

### CITATION LIST

### Patent Literature

Patent Literature 1: International Publication No. 2007/088924

Patent Literature 2: Japanese Patent Laid-Open No. 2004-26641

Patent Literature 3: Japanese Patent Laid-Open No. 119-31244

### SUMMARY OF INVENTION

### Technical Problem

The object of the present invention s to provide: a barium titanate fiber which is particularly useful as a filler for a polymer composite piezoelectric body, a polymer composite piezoelectric body which has high piezoelectric properties, and a piezoelectric element utilizing the polymer composite piezoelectric body.

### Solution to Problem

The inventors have been working diligently to solve the above-described problems. As a result, they found that a polymer composite piezoelectric body having a high piezoelectric constant can be obtained by using a barium titanate fiber as a filler, where the molar ratio of barium atoms to titanium atoms (Ba/Ti ratio) falls within the range from 1.01 to 1.04, and thus completed the present invention.

### Solution to Problem

The present invention has the following structure.

[1.] A barium titanate fiber, wherein a molar ratio of barium atoms to titanium atoms (Ba/Ti ratio) falls within a range of 1.01 to 1.04.

[2] The barium titanate fiber according to [1], which is a short fiber with an average fiber length of 0.5 to 1,000 μm.

[3] The barium titanate fiber according to [1.] or [2], which has an average fiber diameter in a range of 0.1 to 20 μm and an aspect ratio of 2 or greater.

[4] A resin composition, containing the barium titanate fiber according to any one of [1] to [3] and a polymer.

[5] The resin composition according to [4], wherein a ratio of the barium titanate fiber to a total amount of the barium titanate fiber and the polymer is 10% to 90% by volume.

[6] The resin composition according to [4] or [5], further containing 0.1% to 10% by weight of a dispersing agent and/or 0.1% to 10% by weight of a leveling agent with respect to the barium titanate fiber.

[7] The resin composition according to any one of [4] to [6], further containing a solvent.

[8] The resin composition according to any one of [4] to [7], which is used for producing a polymer composite piezoelectric body.

[9] A polymer composite piezoelectric body, containing the resin composition according to any one of [4] to [6].

[10] The polymer composite piezoelectric body according to [9], which has a voltage output constant g₃₃ of 150 mVm/N or greater.

[11] A piezoelectric element, having an electrically conductive layer on one surface or both surfaces of the polymer composite piezoelectric body according to [9] or [10].

[12] A method for producing a barium titanate fiber, including: a process of preparing a spinning solution, a process of preparing a barium titanate fiber precursor by electrostatically spinning the spinning solution, and a process of calcining the precursor, wherein in the process of preparing the spinning solution, the spinning solution is prepared such that a molar ratio of barium atoms to titanium atoms (Ba/Ti ratio) falls within the range of 1.01 to 1.04.

[13] The method for producing a barium titanate fiber according to [12], further including a process of crushing the barium titanate fibers.

[14] A method for producing a polymer composite piezoelectric body, including: a process of obtaining a barium titanate fiber by the producing method according to [12] or [1], a process of preparing a resin composition containing the barium titanate fiber, a polymer, and a solvent, and a process of applying the resin composition to a support by a screen printing method.

### ADVANTAGEOUS EFFECTS OF INVENTION

By using the barium titanate fiber of the present invention as a filler for the polymer composite piezoelectric body, it is possible to obtain a polymer composite piezoelectric body having a high piezoelectric constant.

### DESCRIPTION OF EMBODIMENTS

### Barium Titanate Fiber

In a barium titanate fiber according to the present invention, a molar ratio of barium atoms to titanium atoms (Ba/Ti ratio) falls within a range of 1.01 to 1.04. In other words, the barium titanate fiber of the present invention contains a slight excess of Ba atoms with respect to Ti atoms (Ti:Ba=1.00 mole:1.01 to 1.04 moles). By using such a barium titanate fiber as a filler for a polymer composite piezoelectric body, it is possible to obtain a polymer composite piezoelectric body having a high piezoelectric constant. When the Ba/Ti ratio of the barium titanate fiber is 1.01 or greater, it is considered that the coarsening of the primary particles constituting the fiber can be prevented, and the piezoelectric constant of the polymer composite piezoelectric body can be improved. Meanwhile, when the Bari ratio is 1.04 or lower, components other than the barium titanate can be reduced. From this point of view, the Ba/Ti ratio is preferably within the range of 1.01 to 1.03, and more preferably within the range of 1.01 to 1.02, The Ba/Ti ratio of the barium titanate fiber can be calculated from measurement results of the inductively coupled plasma emission spectroscopy (ICP-AFS) method, the inductively coupled plasma mass spectrometry (ICP-MS) method, the fluorescent X-ray analysis method, and the like. Considering the accuracy of the value, it is preferable to calculate the Ba/Ti ratio by the inductively coupled plasma emission spectroscopy (ICP-AES) method.

The aspect ratio of the barium titanate fiber of the present invention is not particularly limited, but is preferably 2 or greater. A case where the aspect ratio is 2 or greater is preferable because a polymer composite piezoelectric body with excellent piezoelectric properties is obtained when used as a filler for a polymer composite piezoelectric body. The upper limit of the aspect ratio is not particularly limited, but a case where the aspect ratio is 1,000 or lower is preferable because it allows the barium titanate fibers to be uniformly dispersed into the polymer. From this point of view, the aspect ratio of the barium titanate fiber is preferably in the range of 3 to 100, more preferably in the range of 4 to 50, and particularly preferably in the range of 5 to 20. The aspect ratio of the barium titanate fiber can be calculated as (fiber length)/(fiber diameter), for example, from the fiber length and fiber diameter measured from scanning electron micrographs.

The average fiber diameter of the barium titanate fiber of the present invention is not particularly limited, but is preferably in the range of 0.1 to 20 μm, more preferably in the range of 0.2 to 10 μm, and still more preferably in the range of 0.3 to 5 μm. A case where the average fiber diameter is 0.1 μm or greater is preferable because it allows high piezoelectric properties to be obtained in the case of being used as a filler for a polymer composite piezoelectric body. In addition, when the average fiber diameter is 20 μm or less, the thickness of the polymer composite piezoelectric body can be made thinner and the flexibility can be improved. A control method of the fiber diameter is not particularly limited, but the composition (type of solvent, concentration of barium salt and titanium alkoxide, molecular weight and concentration of fiber-forming materials, and the like) of the spinning solution, viscosity of the spinning solution, and electrostatic spinning conditions in the electrostatic spinning process, which will be described later, can be employed, and by appropriately changing these factors, the fiber diameter can be controlled.

The average fiber length of the barium titanate fiber of the present invention is not particularly limited, but is preferably in the range of 0.5 to 1,000 μm, more preferably in the range of 1 to 100 μm, still more preferably in the range of 1.5 to 50 μm, and particularly preferably in the range of 2 to 10 μm. A case where the average fiber length is 0.5 μm or greater is preferable because it allows the piezoelectric and dielectric properties of the polymer composite piezoelectric body to be improved, and a case where the average fiber length is 1,000 μm or less is preferable because it enables uniform dispersion in the polymer or the like. The control method of the fiber length is not particularly limited, but the control is possible by the crushing method or crushing time in the crushing process which will be described later.

In the crystal structure of the barium titanate fiber of the present invention, the ratio (the c/a ratio) of the c-axis to the a-axis in the crystal lattice is preferably 1.005 or greater, more preferably 1.008 or greater, and still more preferably 1.010 or greater. When the c/a ratio is 1.005 or greater, it is possible to provide excellent piezoelectric properties in the case of being used as a filler for the polymer composite piezoelectric body. The crystallite size of the barium titanate fiber is not particularly limited, but is preferably 20 nm or greater, and more preferably 25 nm or greater. When the crystallite size of the barium titanate fiber is 20 nm or greater, it is possible to provide more excellent piezoelectric properties in the case of being used as a filler for the polymer composite piezoelectric body. The control method of the c/a ratio and the crystallite size of the barium titanate fiber is not particularly limited, and examples thereof include changing the calcination temperature, calcination time, and temperature rise rate in the calcination process, which will be described below, and the size of the crystallite can be calculated from measurement results by the X-ray diffraction method.

The barium titanate fiber of the present invention may be either single crystal or polycrystalline (ceramics), but polycrystalline is preferable from the viewpoint of ease of poling and uniformity and isotropy of piezoelectric and dielectric property values. The primary particle diameter in a case where the barium titanate fiber is polycrystalline is not particularly limited, but is preferably in the range of 50 to 3,000 nm, and more preferably in the range of 100 to 1,500 nm. A case where the primary particle diameter is 50 nm or greater is preferable because it can improve the piezoelectric and dielectric properties of the polymer composite piezoelectric body. A case where the primary particle diameter is 3,000 nm or less is preferable because the aspect ratio of the barium titanate fiber is less likely to be reduced by the crushing process or a process of compositing with the polymers. The relationship between the primary particle diameter and the fiber diameter of the barium titanate fiber is not particularly limited, but the fiber diameter is preferably at least 1.5 times the primary particle diameter, and more preferably at least 2 times. A case where the fiber diameter of the barium titanate fiber is at least 1.5 times the primary particle diameter is preferable because it allows the barium titanate fibers with a high aspect ratio to be obtained. The barium titanate fiber of the present invention is not particularly limited, but may contain metal components other than barium and titanium to the extent that the effects of the present invention are not impaired. Such metal components are not particularly limited, and examples thereof include silicon, aluminum, lithium, sodium, potassium, magnesium, calcium, strontium, yttrium, lanthanum, zirconium, hafnium, vanadium, niobium, tantalum, chromium, tungsten, manganese, iron, cobalt, nickel, copper, silver, zinc, boron, indium, tin, lead, or bismuth. The content of the metal component is not particularly limited, but is preferably in the range of 0.1 to 10% by mole, and more preferably in the range of 0.5 to 5% by mole with respect to titanium atoms in the barium titanate fiber. A case where the content is 0.1% by mole or greater is preferable because the effects that satisfy the specifications can be obtained. In addition, a case where the content is 10% by mole or less is preferable because it does not impair the effects of the present invention and allows a polymer composite piezoelectric body with excellent piezoelectric properties to be obtained in the case of being used as a filler for the polymer composite piezoelectric body.

### Method for Producing Barium Titanate Fiber

The method for producing the barium titanate fibers used in the present invention is not particularly limited, and examples thereof include a method for synthesizing barium titanate after forming a solution, melt, slurry, and the like containing barium atoms and titanium atoms in the molar ratio (Ba/Ti ratio) range of 1.01 to 1.04 into a fibrous shape, or a method of performing fibrosis and synthesis at the same time. Among these, the method for synthesizing barium titanate after forming the raw material into a fibrous shape is preferable because it allows both the shape of the barium titanate and the Ba/Ti ratio to be easily controlled. The forming method is not particularly limited, and examples thereof include a mold forming method, a casting method, a doctor blade method, an extrusion molding method, a centrifugal force spinning method, an air blow spinning method, and an electrostatic spinning method, Among these, the electrostatic spinning method is preferable from the viewpoint that the diameter of the barium titanate fiber can be reduced and uniform dispersion in the polymer composite piezoelectric body such as in a thin film is possible. The synthesis method is not particularly limited, and examples thereof include a calcination method, an optical heating method, a discharge plasma sintering method, and a hydrothermal synthesis method.

The following is a description of the method for producing the barium titanate fiber using the electrostatic spinning method, but the present invention is not limited thereto.

The method for producing the barium titanate fiber by the electrostatic spinning method according to the present invention includes a process of preparing a spinning solution (spinning solution preparation process), a process of preparing the barium titanate fiber precursor by electrostatically spinning the spinning solution (electrostatic spinning process), and a process of calcining the precursor (synthesis process).

### Spinning Solution Preparation Process

The spinning solution preparation process in the method for producing the barium titanate fiber by the electrostatic spinning is not particularly limited as long as a spinning solution with spinnability can be obtained, but in order to ensure stable spinning over a long period of time, it is preferable to include the following processes (1) to (3).

### (1) First Solution Preparation Process

In the spinning solution preparation process, first, (1) a process of obtaining a first solution by mixing the barium salt with the first solvent is performed. The barium salt is not particularly limited, and examples thereof include barium carbonate, barium acetate, barium hydroxide, barium oxalate, barium nitrate, barium chloride, and mixtures of these salts. From the viewpoint of solubility in solvents, barium carbonate, barium acetate, and barium nitrate are preferable, The first solvent is not particularly limited as long as the solvent can dissolve the barium salt, but from the viewpoint of uniformity of the finally obtained spinning solution, it is preferable to use an organic acid as a main component, and more preferable to use an acetic acid as a main component. In the present application, “use as a main component” means using it as a component that occupies the largest proportion among the components of the solvent, and means that the component occupies 50% by weight or greater, and more preferably 85% by weight or greater with respect to the total solvent. In other words, the proportion of the organic acid in the first solvent is preferably 50% by weight or greater. Examples of the organic acid include carboxylic acid and sulfonic acid, and carboxylic acid is preferable. Examples of the carboxylic acid may include aliphatic carboxylic acid such as formic acid, acetic acid, and propionic acid, and among these, acetic acid is preferable. The first solvent may contain components other than the organic acid, and examples thereof include water, methanol, ethanol, propanol, acetone, N,N-dimethylformamide, N,N-dimethylacetamide dimethyl sulfoxide, N-methyl-2-pyrrolidone, toluene, xylene, pyridine, tetrahydrofuran, dichloromethane, chloroform, and 1,1,1,3,3,3-hexafluoroisopropanol. From the viewpoint of solubility of barium salts, water (for example, ion-exchanged water) is preferably contained. The ratio of water in the first solvent is preferably 15% by weight or less, more preferably 5% by weight or less, and still more preferably 3% by weight or less, with respect to the total amount of the first solvent. When water is contained in the first solution, the solubility and stability of the first solution is improved, and particularly, when the water content in the first solution is 15% by weight or less, the stability of the spinning solution increases, and thus stable spinning is possible for a long period of time. The concentration of the barium salt in the first solution is not limited as long as the barium salt stably dissolves in the first solution, but the concentration is preferably in the range of 0.1 to 10 mol/L, more preferably in the range of 0.2 to 5 mol/L, and still more preferably in the range of 0.5 to 3 mol/L. A particularly preferable combination of the barium salt and the first solvent is barium carbonate, acetic acid, and water, with a barium carbonate concentration of 1 to 2 mol/L. The mixing conditions in the process (1) are not particularly limited as long as no sludge is produced, and for example, the mixing can be performed at 10 to 90° C. for 1 to 24 hours. The mixing method is not particularly limited as long as the metal salts can dissolve, but the mixing can be performed using known equipment such as a magnetic stirrer, a shaker, a planetary stirrer, and an ultrasonic device.

### (2) Second Solution Preparation Process

In the spinning solution preparation process in the method for producing the barium titanate fiber according to the present invention, in addition to (1), a process of obtaining a second solution by mixing the fiber-forming material, the second solvent, and a titanium alkoxide is performed. The fiber-forming material is not particularly limited as long as spinnability can be provided to the spinning solution, and examples thereof include polyvinyl alcohol, polyethylene glycol, polyethylene oxide, polyvinylpyrrolidone, polyethylene, polypropylene, polyethylene terephthalate, polylactic acid, polyimide, polyurethane, polystyrene, polyvinylidene fluoride, polyacrylonitrile, poly ethyl methacrylate, polyglycolic acid, polycaprolactone, cellulose, cellulose derivatives, chitin, chitosan, collagen, and copolymers and mixtures thereof. As this fiber-forming material, from the viewpoint of solubility in the second solvent and degradability in the calcination process, polyvinyl alcohol, polyethylene glycol, polyethylene oxide, polyvinylpyrrolidone, and polyacrylic acid are preferable, and polyvinylpyrrolidone is more preferable. The weight average molecular weight of the fiber-forming material is not particularly limited, but is preferably in the range of 10,000 to 10,000,000, more preferably in the range of 50,000 to 5,000,000, and still more preferably in the range of 100,000 to 1,000,000. A case where the weight average molecular weight is 10,000 or greater is preferable because the barium titanate fiber has excellent fiber-forming properties, and a case where the weight average molecular weight is 10,000,000 or less is preferable because solubility is excellent and the preparation process is simplified. Regarding the second solvent, from the viewpoint of the stability of the spinning solution, it is preferable to use the alcohol solvent as a main component, more preferable to use a solvent such as ethanol, ethylene glycol, ethylene glycol monomethyl ether, or propylene glycol monomethyl ether as a main component, and still more preferable to use propylene glycol monomethyl ether as a main component. The second solvent may also contain solvents other than the alcoholic solvent, and examples thereof include acetone, N,N-dimethylformamide, N,N-dimethylacetamide, dimethyl sulfoxide, N-methyl-2-pyrrolidone, toluene, xylene, pyridine, tetrahydrofuran, dichloromethane, chloroform, formic acid, acetic acid, and trifluoroacetic acid. The titanium alkoxide is not particularly limited, and examples thereof include titanium tetramethoxide, titanium tetraethoxide, titanium tetranormalpropoxide, titanium tetraisopropoxide, and titanium tetranormalbutoxide. Regarding the stability of the spinning solution and ease of availability, titanium tetraisopropoxide and titanium tetranormalbutoxide are preferable. The concentration of the fiber-forming material and the titanium alkoxide in the second solution is not limited as long as the titanium alkoxide exists stably in the solution together with the fiber-forming material, but for example, the concentration of the fiber-forming, material in the second solvent can be from 1 to 20% by weight, and is preferable from 3 to 15% by weight. A case where the concentration of the fiber-forming material is 1% by weight or greater is preferable because the stability of the second solution is high and the barium titanate fiber easily forms a fibrous shape, and a case where the concentration is 20% by weight or less is preferable because the viscosity of the spinning solution does not become extremely high, stable spinning can be performed, and fine fibers can be easily obtained. The concentration of the titanium alkoxide in the second solvent is preferably in the range of 0.1 to 10mol/L, more preferably in the range of 0.2 to 5 mol/L, and still more preferably in the range of 0.5 to 3 mol/L. Particularly preferable combinations of the fiber-forming material, the secondary solvent, and the titanium alkoxide are polyvinylpyrrolidone, propylene glycol monomethyl ether, and titanium tetraisopropoxide, the concentration of the fiber-forming material in the second solvent is in the range of 5 to 10% by weight, and the concentration of the titanium alkoxide in the second solvent is in the range of 1 to 2 mol/L. The mixing conditions in the process (2) are not particularly limited as long as no sludge is produced, and for example, the mixing can be performed at 10 to 90° C. for 1 to 24 hours. The mixing method is not particularly limited as long as the metal salts can dissolve, but the mixing can be performed using known equipment such as a magnetic stirrer, a shaker, a planetary stirrer, and an ultrasonic device.

### (3) Process of Obtaining Spinning Solution

In the spinning solution preparation process in the method for producing the barium titanate fiber according to the present invention, a process of obtaining the spinning solution by mixing the first solution with the second solution is performed. The method of mixing the first solution with the second solution in the present invention is not limited. In particular, there is no need to perform complicated operations such as mixing small amounts at a time while stirring. Examples of mixing methods include a method of stirring or ultrasonic treatment. The mixing order is not particularly limited, and the first solution may be added to the second solution, the second solution may be added to the first solution, or the first and second solutions may be added to separate containers simultaneously. The ratio of mixing the first solution and the second solution is not particularly limited as long as the molar ratio of barium atoms in the barium salt to titanium atoms in the titanium alkoxide can be adjusted in the range of 1.01:1.00 to 1.04:1.00. The molar ratio can be obtained by dividing the amount of substance of Ba atoms by the amount of substance of Ti atoms (in a case where it is not divisible, it is rounded off to the third decimal place) after obtaining the amount of substance (mole) of Ba and Ti atoms by dividing the weight (g) of the barium salt and the titanium alkoxide by the respective molar mass (g/mol) (in a case where it is not divisible, a numerical value obtained by rounding off the fourth significant digit to three significant digits). When the mixing ratio (weight ratio) of the first solution to the second solution is preferably in the range of 1:3 to 3:1, and more preferably 1:2 to 2:1, the concentration of the barium salt and the titanium alkoxide is not extremely uneven, and the mixing operation can be performed stably.

### Spinning Solution

The viscosity of the spinning solution at the time of spinning in the method for producing the barium titanate fiber according to the present invention is adjusted preferably in the range of 5 to 10,000 cP, and more preferably in the range of 10 to 8,000 cP. When the viscosity is 5 cP or greater, the spinnability for forming fibers is obtained, and when the viscosity is 10,000 cP or less, it is easy to discharge the spinning solution. A case where the viscosity is in the range of 10 to 8,000 cP is more preferable because excellent spinnability can be obtained under a wide range of spinning conditions. The viscosity of the dispersing liquid can be adjusted by appropriately changing the concentration of the barium salt and the titanium alkoxide or the molecular weight, concentration, thickener of the fiber-forming material. The spinning solution may also contain a conductive auxiliary agent for the purpose of improving fiber formation. The conductive auxiliary agent can be used to the extent that the conductive auxiliary agent does not interfere with the uniformity and spinning stability of the spinning solution, and examples thereof include sodium dodecyl sulfate, tetrabutylammonium bromide, and ammonium acetate. A case where the conductive auxiliary agent does not contain metal ions and has the property of completely dissipating in the calcination process is preferable from the viewpoint that a high-purity barium titanate fiber can be obtained. The concentration of the conductive auxiliary agent is set appropriately depending on the solvent used and the type of fiber-forming material, and is not particularly limited, but the concentration of the conductive agent is preferably in the range of 0.001 to 1% by weight, and more preferably in the range of 0.01% to 0.1% by weight of the spinning solution. A case where the concentration of the conductive auxiliary agent is 0.001% by weight or greater is preferable because it improves the effect suitable for use, and when the concentration is 1% by weight or less, a high-purity barium titanate fiber can be obtained. The spinning solution may also contain stabilizers with multidentate ligands such as ethylenediamine, ethylenedinitrilotetraacetic acid, acetylacetone, citric acid, and malic acid for the purpose of stabilizing barium and titanium ions. Components other than those described above may be contained as components of the spinning solution as long as the components do not significantly impair the effects of the present invention. For example, a viscosity modifier, a pH modifier, and a preservative may be contained. These additives may be added to the first solution, may be added to the second solution, or may be added after mixing the first solution with the second solution.

### Electrostatic Spinning Process

In this method for producing barium titanate fiber according to the present invention, the barium titanate fiber precursor is obtained by electrostatically spinning the prepared spinning solution. The electrostatic spinning method is a method for obtaining fibers on a collector by discharging the spinning solution, applying an electric field, and fiberizing the discharged spinning solution. Examples of the electrostatic spinning method include a method of spinning by extruding the spinning solution through a nozzle and applying an electric field, a method of spinning by bubbling the spinning solution and applying an electric field, and a method of spinning by guiding the spinning solution on the surface of a cylindrical electrode and applying an electric field. According to this method, uniform fibers with a diameter of 10 nm to 10 μm can be obtained.

Examples of the method for discharging the spinning solution include a method for discharging the spinning solution that fills a syringe using a pump through a nozzle. The temperature of the spinning solution at the time of spinning may be room temperature, high temperature by heating, or low temperature by cooling. The inner diameter of the nozzle is not particularly limited, but is preferably in the range of 0,1 to 1.5 mm. The discharge amount is not particularly limited, but is preferably between 0.1 and 10 mL/hr. A case where the discharge amount is 0.1 mL/hr or greater is preferable because sufficient productivity of barium titanate fiber can be obtained, and a case where the discharge amount is 10 mL/hr or less is preferable because it is easy to obtain uniform and fine fibers. The polarity of the applied voltage can be positive or negative, The magnitude of the voltage is not particularly limited as long as fibers are formed, and for example, in a case of a positive voltage, the range of 5 to 100 kV can be used as an example. The method for applying an electric field is not particularly limited as long as the electric field can be formed to the nozzle and the collector, and for example, the collector may be grounded by applying a high voltage to the nozzle, the nozzle may be grounded by applying a high voltage to the collector, and a high negative voltage may be applied to the collector by applying a high positive voltage to the nozzle. The distance between the nozzle and the collector is not particularly limited as long as fibers are formed, but examples thereof include a range of 5 to 50 cm. The collector may be able to collect the spun fibers, and the material and shape thereof are not particularly limited. Conductive materials such as metals are suitable as the material for the collector. The shape of the collector is not particularly limited, but can be, for example, a shape of a flat plate, a shaft, or a conveyor. When the collector has a shape of a flat plate, fiber assemblies can be collected in a shape of a sheet, and when the collector has a shape of a shaft, fiber assemblies can be collected in a shape of a tube. When the collector has a shape of a conveyor, it is possible to continuously produce fiber assemblies that are collected in a shape of a sheet.

The fiber assembly may be collected in a collecting body installed between the nozzle and the collector. A collecting body with a volume resistivity value of 10¹⁰ Ω·cm or less is preferred, and one with a volume resistivity of 10⁸ Ω·cm or less is more preferred. Materials with a volume resistivity value exceeding 10¹⁰ Ω·cm can also be suitably used in conjunction with ionizers and other devices that dissipate electric charges. As a collecting body of any shape is used, the fiber assembly can be collected according to the shape of the collecting body. Furthermore, it is also possible to use a liquid as the collecting body.

### Synthesis Process

The electrostatically spun barium titanate fiber precursor goes through the synthesis process such as calcination to heat and decompose the fiber-forming materials and the like contained in the barium titanate fiber precursor, and the barium titanate fiber with high quality and high crystallinity can be obtained. For calcination, a common electric furnace can be used. The calcination atmosphere is not particularly limited, but calcination can be performed in the air atmosphere or inert gas atmosphere. A case where calcination in the air atmosphere is preferable because the amount of residual material, such as fiber-forming material is reduced, and a high-purity barium titanate fiber can be obtained. The calcination method may be single-step calcination or multi-step calcination. The calcination temperature is not particularly limited, but is preferably in the range of 1,000 to 1,500° C., more preferably in the range of 1,050 to 1,300° C., and particularly preferably in the range of 1,100 to 1,200° C. When the calcination temperature is 1,000° C. or greater, the calcination is sufficient, the c/a ratio of the barium titanate fiber becomes large, and the piezoelectric and dielectric properties of the polymer composite piezoelectric body can be improved. A case where the temperature is 1,500° C. or less is preferable because the primary particles of barium titanate fibers do not coarsen, the aspect ratio can be increased, and the energy consumption can be suppressed to be low. When the calcination temperature is in the range of 1,050 to 1,300° C., particularly, 1,100 to 1,200° C., the purity and crystallinity are sufficiently high, the coarse fibers are small, and the production cost can be sufficiently low. The calcination time is not particularly limited, but for example, calcination may be performed for 1 to 24 hours. The temperature rise rate is not particularly limited, but can be appropriately changed in the range of 5 to 200° C./min to perform the calcination. The barium titanate fiber assemblies having various shapes can be obtained by forming the electrostatically spun barium titanate fiber precursor into any shape to perform the calcination. For example, sheet-shaped barium titanate fiber assemblies can be obtained by forming and calcining the barium titanate fiber precursor into a two-dimensional sheet shape, and tube-shaped barium titanate fiber assemblies can be obtained by wrapping the barium titanate fiber precursor around a shaft and collecting the barium titanate fiber precursor. It is also possible to obtain cotton-shaped barium titanate fiber assemblies by collecting the barium titanate fiber precursor in a liquid, freeze-drying the barium titanate fiber precursor, forming the barium titanate fiber precursor into a shape of cotton, and calcining the barium titanate fiber precursor.

### Crushing Process

Regarding the barium titanate fiber of the present invention, it is desirable to further refine the barium titanate fibers obtained by calcination by the crushing process or the like. The crushing process makes it easier to fill the polymer matrix as a filler. In general, examples of the method for crushing process include ball mills, bead mills, jet mills, high-pressure homogenizers, planetary mills, rotary crushers, hammer crushers, cutter mills, stone mills, mortars, and screen mesh crushing, and the method may be either a dry type or a wet type. However, from the viewpoint that it is possible to increase the aspect ratio of barium titanate fiber, screen mesh crushing is preferably used. Examples of the screen mesh crushing include a method of placing barium titanate fiber on a mesh with a predetermined mesh opening and filtering the barium titanate fiber with a brush or spatula, and a method of placing beads such as alumina, zirconia, glass, PTFE, nylon, and polyethylene and barium titanate fiber on a mesh and applying longitudinal and/or lateral vibration. The mesh opening used is not particularly limited, and is preferably in the range of 20 to 1000 μm, and is more preferably in the range of 50 to 500 μm. A case where a mesh opening is 20 μm or greater is preferable because it is possible to increase the aspect ratio of the barium titanate fiber and reduce the crushing process time, and a case where a mesh opening is 1000 μm or less is preferable because coarse and aggregated barium titanate fibers can be removed. Depending on the required properties, the crushing method and conditions can be appropriately changed. In the present invention, fragments (barium titanate short fibers) that have been refined by the crushing process are also included in barium titanate fibers.

Examples of the most preferable method for producing the barium titanate fiber according to the present invention include a method for screen mesh crushing the fired fibers by preparing the precursor by electrostatically spinning the spinning solution obtained by mixing the titanium alkoxide with the barium salts such that the Ba/Ti ratio is 1.01 to 1.04 and by calcining the precursor at 1000° C. or greater.

The barium titanate fibers used in the present invention are not particularly limited, but may be surface-treated with silane coupling agents, titanium coupling agents, aluminum coupling agents, zirconium coupling agents, and zircoaluminate coupling agents. The functional groups at the end of the coupling agent are not particularly limited, examples thereof include amino, fluoro, acryloyl, epoxy, ureido, and acid anhydride groups, and these can be appropriately selected according to the properties of the polymer to be combined.

### Resin Composition

The resin composition of the present invention includes the barium titanate fibers and a polymer, The polymer used in the present invention is not particularly limited as long as the dispersibility of barium titanate fibers is excellent and flexibility is provided to the polymer composite piezoelectric body, as a matrix of the polymer composite piezoelectric body. The polymer may be a thermoplastic polymer, a thermosetting polymer, or a photosetting polymer. Examples of thermoplastic polymers include polyvinyl alcohol, polyethylene glycol, polyethylene oxide, polyvinylpyrrolidone, polyethylene, polypropylene, polyethylene terephthalate, polylactic acid, polyamide, polyurethane, polystyrene, polyvinylidene fluoride, vinylidene fluoride polymer (for example, copolymer of vinylidene fluoride and hexafluoropropylene, copolymer of vinylidene fluoride and trifluoroethylene, and copolymer of vinylidene fluoride and tetrafluoroethylene), cyanoethylated polyvinyl alcohol, cyanoethylated purulan, cyanoethylated cellulose, polyacrylonitrile, polymethyl methacrylate, polyglycolic acid, polycaprolactone, polyvinylformal, polyvinyl butyral, polysulfone, polyethersulfone, cellulose, cellulose derivatives, chitin, chitosan, collagen, and copolymers and mixtures of these. Examples of thermosetting polymers include epoxy compound, oxetane compound, phenol resin, polyimide resin, (meth)acrylic resin with crosslinkable functional groups, and copolymers and mixtures of these. Examples of photosetting polymers include acrylate-based photocurable resin (for example, urethane acrylate and polyester acrylate) and epoxy-based photocurable resin, and known photoinitiators can be used. Among these, vinylidene fluoride polymers are particularly preferable from the viewpoint of providing excellent flexibility, voltage resistance, and dielectric properties to polymer composite piezoelectric body. The polymer may or may not have piezoelectric properties in itself, but a case of using a polymer that does not have piezoelectric properties is preferable because the piezoelectric properties of the barium titanate fiber are not canceled and a high piezoelectric constant can be obtained. Meanwhile, it is also possible to obtain a high pyroelectric constant by using a polymer having pyroelectric properties in itself, due to the synergistic effect with the pyroelectric effect of barium titanate fibers. By using an elastomer as a polymer, a dielectric elastomer that takes advantage of high relative dielectric constant of the barium titanate fiber can also be used. Such an elastomer is not particularly limited, but an elastomer with a high dielectric constant and a low elastic modulus is preferable. Examples thereof include a silicon elastomer, acrylic elastomer, a fluoroelastomer, an amide elastomer, an ester elastomer, and an olefin elastomer.

The weight average molecular weight of a polymer used in the present invention is not particularly limited, but is preferably in the range of 10,000 to 10,000,000, more preferably in the range of 50,000 to 5,000,000, and still more preferably in the range of 100,000 to 1,000,000. A case where the weight average molecular weight is 10,000 or greater is preferable because the mechanical properties and handleability of the polymer composite piezoelectric body are improved, and a case where the weight average molecular weight is 10,000,000 or less is preferable because solubility and thermoplasticity are excellent and processing is easy.

In the resin composition of the present invention, the ratio of barium titanate fibers to the total amount of polymer and barium titanate fibers is not particularly limited, but is preferably in the range of 10 to 90% by volume, more preferably in the range of 30 to 85% by volume, and still more preferably 50 to 80% by volume (or to 75% by volume, or to 70% by volume). A case where the ratio of barium titanate fiber is 10% by volume or greater is preferable because it allows the polymer composite piezoelectric body with excellent piezoelectric and dielectric properties to be obtained, and a case where the ratio is 90% or less by volume is preferable because it allows the polymer composite piezoelectric body with excellent flexibility to be obtained.

The resin composition of the present invention is not particularly limited, but as a component other than the polymer and barium titanate fibers, a dispersing agent may be contained. The dispersing agent is not particularly limited as long as barium titanate fibers in the polymer matrix can be uniformly dispersed, and may be a low molecular weight dispersing agent or a polymeric dispersing agent. Examples of the low molecular weight dispersing agent include anionic surfactants such as sodium dodecyl sulfate, cationic surfactants such as tetrabutylammonium bromide, and nonionic surfactants such as polyoxyethylene sorbitan monolaurate. As this polymeric dispersing agent, for example, nonionic, cationic, and anionic systems can all be selected. Among these polymeric dispersing agents, those with an amine value and an acid value are preferable, and specifically, those with an amine value of 5 to 200 and an acid value of 1 to 100 in terms of solid content are preferable. As examples, “Solsperse” (produced by Lubrizol Corporation) 24000, “EFKA” (produced by Ciba Specialty Chemicals Holding Inc.) 4046, “Azisper” (produced by Ajinomoto Fine-Techno Co., Inc) PB821, “BYK” (produced by BYK-Chemie) 160, and the like can be preferably used. The content of the dispersing agent is preferably in the range of 0.1 to 10% by weight with respect to the barium titanate fibers, more preferably in the range of 0.2 to 5% by weight, and still more preferably in the range of 0.5 to 3% by weight. A case where the content of the dispersing agent is 0.1% by weight or greater with respect to the barium titanate fibers is preferable because it allows the barium titanate fiber to disperse in the polymer and high piezoelectric and dielectric properties to be obtained, and a case where the content is 10% by weight or less is preferable because the properties of the polymer and barium titanate fibers can be maintained. Depending on the target properties, additives other than the dispersing agent may be contained to the extent that the effects of the present invention are not impaired. Examples of the additives include polymer compounds, epoxy compounds, acrylic resins, inorganic particles, metal particles, surfactants, antistatic agents, leveling agents, viscosity modifiers, thixotropy modifiers, adhesion improvers, epoxy curing agents, corrosion inhibitors, preservatives, mold inhibitors, antioxidants, reduction inhibitors, evaporation accelerators, chelating agents, pigments, titanium black, carbon black, and dyes. Only one of these additives may be used, or a combination of two or more may be used as appropriate, depending on the target properties. In particular, the leveling agent is not particularly limited as long as surface defects such as unevenness and bouncing of the coating film can be improved when the resin composition is applied to the support, may be a low molecular weight leveling agent or a polymeric leveling agent. Examples of the low molecular weight leveling agent include “BYK” (produced by BYK-Chemie) 361N, and “SURFLON” (produced by AGC Seimi Chemical Co., Ltd.) S-232. Examples of the polymeric leveling agent include “BYK” (produced by BYK-Chemie) 354, and “MEGAFACE” (produced by DIC Corporation) F-563. The content of the leveling agent is preferably in the range of 0.1 to 10% by weight with respect to the barium titanate fibers, more preferably in the range of 0.2 to 5% by weight, and still more preferably in the range of 0.5 to 3% by weight. A case where the content of the leveling agent is 0.1% by weight or greater with respect to the barium titanate fibers is preferable because it can improve the surface defects of the coating film and high piezoelectric and dielectric properties can be obtained, and a case where the content is 10% by weight or less is preferable because the properties of the polymer and barium titanate fibers can be maintained. The leveling agent may be used in combination with a dispersing agent, or only a leveling agent may be used without a dispersing agent.

The resin composition of the present invention is not particularly limited, but may further contain a solvent. Solvents used for resin compositions are not particularly limited as long as it is possible to uniformly disperse and dissolve barium titanate fibers, polymers, and other additives, and examples thereof include water, methanol, ethanol, propanol, acetone, methyl ethyl ketone, methyl isobutyl ketone, cyclohexanone, N,N-dimethylformamide,

N,N-dimethylacetamide, N,N-dimethylpropionamide, dimethyl sulfoxide, N-methyl-2-pyrrolidone, ethyl acetate, butyl acetate, propylene carbonate, diethylene carbonate, toluene, xylene, pyridine, tetrahydrofuran, dichloromethane, chloroform, 1,1,1,3,3,3-hexafluoroisopropanol, triethyl phosphate, formic acid, and acetic acid. A mixture of one or more of these solvents may be used. In a case of using vinylidene fluoride polymer as a polymer, as the solvents, it is preferable to use N,N-dimethylformamide, N,N-dimethylacetamide, N,N-dimethylpropionamide, dimethyl sulfoxide, N-methyl-2-pyrrolidone, acetone, methyl ethyl ketone, methyl isobutyl ketone, cyclohexanone, tetrahydrofuran, triethyl phosphate, and a mixed solvent of these.

The concentration of the solvent in the resin composition of the present invention is not particularly limited as long as uniform application is possible to produce the polymer composite piezoelectric body, but the concentration is preferably in the range of 5 to 95% by weight, more preferably in the range of 20 to 90% by weight, and still more preferably in the range of 30 to 80% by weight.

The viscosity of the resin composition of the present invention is not particularly limited, and generally, a case of adjusting the viscosity to be in the range of 1 to 1,000 cP is preferred for improving workability of the coating process, the viscosity is more preferably in the range of 5 to 5,000 cP, and still more preferably in the range of 10 to 2,000 cP.

In a case where the resin composition of the present invention is applied by the screen printing method, a case where the viscosity of the resin composition is preferably in the range of 100 to 50,000 cP, more preferably in the range of 200 to 3,000 cP, and still more preferably in the range of 500 to 20,000 cP.

The resin composition of the present invention may be in the form of a powder (for example, a powder mixture obtained by mixing a polymer, barium titanate fibers, and any dispersing agent and/or leveling agent), may be in the form of pellets or the like (for example, pellets obtained by kneading a polymer, barium titanate fibers, and any dispersing agent and/or leveling agent), or may be in the form of a liquid such as solution and dispersing liquid (for example, a liquid composition such as a coating composition, ink, varnish, which contains a polymer, barium titanate fiber, and a solvent, and contains any dispersing agent and/or a leveling agent). The resin composition of the present invention can be used to produce a polymer composite piezoelectric body.

### Method for Producing Polymer Composite Piezoelectric Body

The polymer composite piezoelectric body of the present invention can be produced by forming the above-described resin composition into any shape and then performing poling processing. The forming method of the resin composition is not particularly limited, and may be a melting method using the powdered or pellet-shaped resin composition of the present invention, or may be a solution method using a liquid resin composition. The melting method is preferable because a solvent is not required and the polymer composite piezoelectric body can be obtained by thermal melting. The solution method is preferable because the uniformity of the obtained polymercomposite piezoelectric body is excellent. Examples of the shape of the polymer composite piezoelectric body include shapes of a film, fiber, non-woven fabric, and block, but the shape of a film is preferable. In the following, the method for producing the film-shaped polymer composite piezoelectric body is described, but the method is not limited thereto.

Examples of the method for producing a polymer composite piezoelectric body by the solution method include a method of spreading and drying a liquid resin composition. The resin composition of the present invention used in the solution method further contains a solvent in addition to the polymer and barium titanate fibers (and any dispersing agent and/or leveling agent) described above. Solvents used in the resin compositions can be used as solvents at the above-described concentrations. The method for preparing the liquid resin composition is not particularly limited, but can be performed using known equipment such as magnetic stirrers, shakers, ball mills, jet mills, planetary stirrers, and ultrasonic devices. The preparation conditions are not particularly limited, but for example, the preparation can be performed at 10 to 120° C. for 1 to 24 hours. The method of applying a liquid resin composition to form a sheet or a thin film is not particularly limited, and the application can be performed using known methods such as spin coating method, spray coating method, roll coating method, slit coating method, gravure coating method, and cast coating method. In a case where patterning is required to prepare piezoelectric elements and the like, the patterning can be performed using known methods such as ink jet method, screen printing method, and flexographic printing method. Supports for applying the liquid resin composition is not particularly limited, and glass substrates, aluminum substrates, copper substrates, and polymer films can be used. The polymer composite piezoelectric body may be left as a film on the support, or a support with a release treated surface may be used to form a freestanding film. As a support, by using a support in which an electrically conductive layer such as aluminum, copper, indium tin oxide, PEDOT/PSS, or conductive paste is formed on a substrate such as glass substrate, aluminum substrate, copper substrate, or polymer film, the liquid resin composition is applied thereon and dried to form a polymer composite piezoelectric body, which can also be used to produce piezoelectric elements as described below. A method of drying the solvent is not particularly limited, and examples thereof include induction heating, hot air circulation heating, vacuum drying, infrared, and microwave heating methods. Drying conditions may include, for example, drying at 40 to 150° C. for 1 to 180 minutes. After drying, the polymer composite piezoelectric body can be further subjected to heat pressing or heat treatment for the purpose of promoting uniformity and crystallization. The heat press conditions are not particularly limited, and examples thereof include a condition with press temperature from 60 to 250° C., pressing pressure from 1 to 30 MPa, and pressing time from 1 to 60 minutes. Heat treatment conditions may include, for example, 1 to 24 hours at 60 to 200° C. in an oven.

Examples of the method for producing a polymer composite piezoelectric body by the melting method includes a method in which a powdered or pellet-shaped resin composition (the above-described polymer, barium titanate fiber, resin composition containing any dispersing agent and/or leveling agent) is melt-kneaded and hot-pressed. The heat press conditions are not particularly limited, and the press to temperature may be greater than the melting or softening temperature of the polymer, and for example, at least 20° C. greater than the melting or softening temperature is preferable. Examples of the pressing pressure include a pressure of 1 to 30 MPa. Basically, higher pressure is preferable. However, it is preferable to appropriately change the pressure by flowability and the target physical properties (for example, which direction of piezoelectric properties is important), and apply a suitable pressure. The pressing time is preferably within the range that does not impair the properties of the polymer composite piezoelectric body, and a range of 1 to 20 minutes can be used as an example. When the pressing time is 1 minute or greater, the polymer and fibrous filler can be mixed with each other sufficiently, and when the pressing time is 20 minutes or less, it is possible to suppress decrease in the molecular weight of the polymer, and the physical properties of the polymer composite piezoelectric body is not impaired.

The molded resin composition formed in this manner can be further made into a polymer composite piezoelectric body by poling processing. Examples of the poling processing method include corona poling or contact poling. Corona poling can be preferably used for the production of large-area polymer composite piezoelectric body because it is possible to continuously process roll-shaped polymer composite piezoelectric body. The corona poling can be performed, for example, by installing the formed resin composition on a flat electrode equipped with heating means, and by applying a high voltage to a needle-shaped electrode 1 to 50 mm away from the resin composition. The temperature of the heating means can be selected appropriately depending on the type of polymer or titanate metal salt that constitutes the polymer composite piezoelectric body, for example, in the range of 40 to 120° C. The applied voltage and time are not particularly limited as long as polarization s possible, and the range of 1 to 20 kV and 10 to 600 seconds can be used as examples. The corona poling can be performed multiple times, for example, may be performed 10 times for 10 seconds each. Meanwhile, the contact poling can be used preferably in a case where polymer composite piezoelectric bodies are stacked or patterned to prepare devices and the like. The contact poling can be performed, for example, by sandwiching the formed resin composition between upper and lower flat electrodes and applying a voltage directly thereto. The flat electrode may be heated, and the temperature can be appropriately selected according to the type of polymer and titanate metal salt, for example, in the range of 40 to 120° C. The strength of the applied electric field and the application time are not particularly limited, as long as polarization is possible, and 1 to 20 kV/mm and 1 to 60 minutes can be used as examples.

### Polymer Composite Piezoelectric Body

The polymer composite piezoelectric body of the present invention combines high piezoelectric and dielectric properties with excellent flexibility because the polymer matrix is filled with the above-described barium titanate fibers.

A piezoelectric constant d₃₃ of the polymer composite piezoelectric body of the present invention is not particularly limited, but the piezoelectric constant d₃₃ is preferably 75 pC/N or greater, more preferably 80 pC/N or greater, and still more preferably 90 pC/N or greater. In addition, a voltage output constant g₃₃ of the polymer composite piezoelectric body is not particularly limited, but the voltage output constant g₃₃ is preferably 150 mVm/N or greater, more preferably 200 mVm/N or greater, and still more preferably 250 mVm/N or greater. A case where g₃₃ is 150 mVm/N or greater is preferable because it can improve the sensitivity of the sensor. The power generation performance index of the polymer composite piezoelectric body is not particularly limited, but the power generation performance index is preferably 15.0×10⁻¹⁵ VCm/N², more preferably 20.0×10⁻¹⁵ VCm/N², and still more preferably 25.0×10⁻¹⁵ VCm/N². A case where the power generation performance index is 15.0×10⁻¹⁵ VCm/N² is preferable because it can improve the power generation performance as a power generation device.

The elastic modulus of the polymer composite piezoelectric body of the present invention is not particularly limited, but is preferably in the range of 100 to 10,000 MPa, more preferably in the range of 200 to 5,000 MPa, and still more preferably 500 to 3,000 MPa or less. A case where the elastic modulus of the polymer composite piezoelectric body is 10,000 MPa or less is preferable because the flexibility and processability of the polymer composite piezoelectric body is improved, and a case where the elastic modulus is 100 MPa or greater is preferable because the generating power of the polymer composite piezoelectric body is improved. Meanwhile, a polymer composite piezoelectric body with an elastic modulus of less than 100 MPa can be used in applications where further elasticity and flexibility are required.

Breaking elongation of the polymer composite piezoelectric body of the present invention is not particularly limited, but is preferably 10% or greater, more preferably 30% or greater, and still more preferably 100% or greater. A case where the breaking elongation is 10% or greater is preferable because the processing into any shape can be easily performed and applications to large deformation are also possible.

Relative dielectric constant of the polymer composite piezoelectric body of the present invention is not particularly limited, but is preferably 10 or greater, more preferably 20 or greater, and still more preferably 50 or greater. When the relative dielectric constant of the polymer composite piezoelectric body is 10 or greater, it is possible to obtain large deformation when a voltage is applied. Such a polymer composite piezoelectric body with a large relative dielectric constant can be suitably used for applications that convert electric energy into mechanical energy, such as actuators and electroacoustic conversion equipment. Meanwhile, even in a case where the relative dielectric constant is low, the polymer composite piezoelectric body can be suitably used for applications such as sensors and power generation devices that convert mechanical energy into electric energy. The relative dielectric constant of the polymer composite piezoelectric body is not particularly limited, but is preferably 70 or less, more preferably 60 or less, and still more preferably 50 or less.

Melting temperature or softening temperature of the polymer composite piezoelectric body of the present invention is not particularly limited, but the melting temperature or softening temperature is preferably 60° C. or greater, more preferably 80° C. or greater, and still more preferably 100° C. or greater. When the melting temperature or softening temperature is 60° C. or greater, the heat resistance of the polymer composite piezoelectric body can be improved and the polymer composite piezoelectric body can also be used in high temperature environments.

The thickness of the polymer composite piezoelectric body of the present invention is not particularly limited, but is preferably in the range of 5 to 500 μm, more preferably in the range of 10 to 200 μm, and still more preferably 20 to 100 μm. A case where the thickness of the polymer composite piezoelectric body is 5 μm or greater is preferable because the mechanical strength can be maintained, and a case where the thickness is 500 μm or less is preferable because the flexibility is excellent.

The polymer composite piezoelectric body of the present invention has a high piezoelectric constant and excellent flexibility, and can be suitably used for electroacoustic conversion equipment such as speakers and buzzers, actuators, tactile displays, sensors, and power generation devices.

### Piezoelectric Element

The piezoelectric element of the present invention has an electrically conductive layer on one surface or both surfaces of the polymer composite piezoelectric body. The electrically conductive layer is not particularly limited, and palladium, iron, aluminum, copper, nickel, platinum, gold, silver, chromium, molybdenum, indium tin oxide, PEDOT/PSS, carbon, or conductive paste can be used. Among these, aluminum, copper, platinum, gold, silver, indium tin oxide, PEDOT/PSS, or conductive paste is preferable. The thickness of the electrically conductive layer is not particularly limited, but is preferably in the range of 0.1 to 20 μm. The electrically conductive layer can be provided with a convex protruding part for drawing out the electrodes. The formation method of such electrically conductive layers is not particularly limited, and the formation can be performed using known methods such as vapor deposition method such as vacuum evaporation or sputtering, spin coating method, spray coating method, roll coating method, gravure coating method, cast coating method, ink jet method, screen printing method, or flexographic printing method.

The piezoelectric element of the present invention may further have an insulating layer outside the electrically conductive layer for the purpose of protecting the polymer composite piezoelectric body and conductive layer, and improving mechanical strength and handleability. The insulating layer is not particularly limited as long as insulation and mechanical properties can be provided, and polyethylene, polypropylene, polyethylene terephthalate, polybutylene terephthalate, polystyrene, polycarbonate, polymethyl methacrylate, polyimide, thermosetting resin, photosetting resin, glass, polyethylene naphthalate, and the like can be used. Among these, polyethylene naphthalate, which has a thermal shrinkage rate of less than 3.0% at 150 to 200° C., is suitably used. By providing an insulating layer having heat resistance, a heat-pressing process to smooth the surface of the polymer composite piezoelectric body is possible, and it is possible to withstand a shelf test and a driving test at high temperatures. The thickness of the insulating layer is not particularly limited, but is preferably 100 μm or less, more preferably 50 μm or less, and still more preferably 30 μm or less. When the thickness of the insulating layer is 100 μm or less, the conversion of mechanical and electric energy can be performed efficiently.

The laminated structure of the piezoelectric element of the present invention is not particularly limited, and examples thereof include a two-layer structure of a polymer composite piezoelectric body and a conductive layer, a three-layer structure of a first electrically conductive layer, a polymer composite piezoelectric body, and a second electrically conductive layer, a five-layer structure of a first insulating layer, a first electrically conductive layer, a polymer composite piezoelectric body, a second electrically conductive layer, and a second insulating layer, and a seven-layer structure of a first insulating layer, a first electrically conductive layer, a first polymer composite piezoelectric body, a second electrically conductive layer, a second polymer composite piezoelectric body, a third electrically conductive layer, and a second insulating layer. The number of layers of the laminated structure and the composition or material of each layer may be appropriately changed depending on the required characteristics. In a case where the piezoelectric element has a plurality of electrically conductive layers, insulating layers, and polymer composite piezoelectric bodies, each layer may have the same or different components. The layers other than the polymer composite piezoelectric body, the electrically conductive layer, and the insulating layer may be provided to the extent that the effects of the present invention are not impaired.

The method for producing a piezoelectric element having such a laminated structure is not particularly limited, but the screen printing method is preferable. The method for producing a piezoelectric element, inch has the five-layer structure of a first insulating layer, a first electrically conductive layer, a polymer composite piezoelectric body, a second electrically conductive layer, and a second insulating layer, using the screen printing method is not particularly limited, and examples thereof include a process of forming the first electrically conductive layer by screen-printing the conductive paste on the film-shaped first insulating layer, a process of forming the polymer composite piezoelectric body by screen-printing the liquid resin composition on the first electrically conductive layer and performing the poling processing, a process of forming the second electrically conductive layer by screen-printing the conductive paste on the polymer composite piezoelectric body, and a process of forming the second insulating layer by screen-printing the thermosetting resin on the second electrically conductive layer and performing the thermosetting. Stainless steel, nylon, or polyester can be used as a material of the screen for the screen printing method, and a structure in which the mesh number is 60 to 650, the aperture ratio is 30% to 70%, and the mesh opening is 20 to 300 μm can be used as an example of a screen structure. The screen-printing conditions are not particularly limited, and conditions in which the squeegee pressure is in the range of 0.01 to 0.5 MPa, the squeegee angle is in the range of 45° to 90°, the squeegee attack angle is in the range of 30° to 90°, the squeegee hardness is in the range of 60° to 90°, the squeegee speed is in the range of 10 to 150 mm/s, and the clearance is in the range of 1.0 to 20 mm can be used as an example

### Examples

The invention will be described in more detail by the following examples, but they are merely for illustration. The scope of the present invention is not limited to them. The measurement methods or definitions of the physical properties used in the examples is shown below.

### Average Fiber Length, Average Fiber Diameter, and Aspect Ratio of Barium Titanate Fiber

The obtained titanium barium fibers were observed at 5,000 to 30,000 times magnification using a scanning electron microscope (SU-8000) manufactured by Hitachi, Ltd., the fiber length and fiber diameter of 100 or more barium titanate fibers were measured using image analysis software, each of the average values was set as the average fiber length and average fiber diameter, and the average value of (fiber length)/(fiber diameter) was set as the aspect ratio.

### Ba/Ti Ratio of Barium Titanate Fiber

0.05 g of the obtained barium titanate fiber was collected in a quartz beaker, and 38 mL of ultrapure water, 2 mL of hydrogen peroxide, and 10 mL of nitric acid were added and dissolved at 100° C. Then, using a 100-fold diluted solution, the concentration of the barium and titanium atoms were measured by inductively coupled plasma emission spectroscopy analysis (ICP-AES) device (iCAP 6300) manufactured by Thermo Fisher Scientific. From the obtained concentrations, the amount of substance (mole) of barium and titanium atoms was calculated, and the Ba/Ti ratio was calculated.

### c/a Ratio of Barium Titanate Fiber

Using X-ray diffractometer manufactured by Bruker Corporation (D8 DISCOVER), the obtained barium titanate fiber was irradiated with CuKα rays, and the CuKα rays reflected from the sample were detected to obtain a diffraction image. From the obtained diffraction. image, the c/a ratio was acquired by using sinθ₍₂₀₀₎/sinθ₍₀₀₂₎ from the diffraction angles θ₍₀₀₂₎ and θ₍₂₀₀₎ of peaks of the (002) and (200) planes.

### Piezoelectric Constant d₃₃ of Polymer Composite Piezoelectric Body

Using a d₃₃ meter manufactured by Lead Techno Co., Ltd., a polymer composite piezoelectric body was sandwiched between the terminals at 1 N and the piezoelectric constant d₃₃ was measured under the conditions of preload force 1N and load force 4N. The average value of the d₃₃ values obtained from the measurement was used as the d₃₃ of the polymer composite piezoelectric body.

### Relative Dielectric Constant of Polymer Composite Piezoelectric Body

The conductive surfaces were formed on both surfaces of the polymer composite piezoelectric body by using DOTITE (D-362) manufactured by FUJIKURA KASEI CO., LTD., and by using the impedance analyzer (IM 3570) manufactured by HIOKI E.E. CORPORATION and super insulation meter and shielding box (SMF-8350), the capacitance at a frequency of 1 kHz was measured, and the relative dielectric constant was calculated from the capacitance and the thickness of the polymer composite piezoelectric body.

### Voltage Output Constant g₃₃ of Polymer Composite Piezoelectric Body

The voltage output constant g₃₃ of the polymer composite piezoelectric body was calculated from the piezoelectric constant d₃₃ and the relative dielectric constant of the polymer composite piezoelectric body by the following relational expression. Here, as the dielectric constant of the vacuum, 8.854×10⁻¹² C/Vm was used.

g₃₃=d₃₃÷(relative dielectric constant)÷(dielectric constant of vacuum)

### Power Generation Performance Index of Polymer Composite Piezoelectric Body

The power generation performance index of the polymer composite piezoelectric body was calculated from the piezoelectric constant d₃₃ and the voltage output constant g₃₃ of the polymer composite piezoelectric body by the following relational expression.

Power generation performance index=d₃₃×g₃₃/1000

### Example 1

### Preparation of Spinning Solution

15.79 parts by weight of barium carbonate, 60 parts by weight of acetic acid, and 0.06 part by weight of ion-exchanged water were mixed to obtain the first solution. Then, 3.6 parts by weight of polyvinylpyrrolidone, 56.4 parts by weight of propylene glycol monomethyl ether, and 22.51 parts by weight of titanium tetraisopropoxide were mixed to obtain the second solution. By mixing the obtained first solution with the second solution, a spinning solution 1 with a Ba/Ti ratio of 1.01 was prepared.

### Preparation of Fibers

The spinning solution 1 prepared by the above method was supplied to a nozzle with an inner diameter of 0.22 mm by a syringe pump at a rate of 2.0 mL/hr, and at the same time, a voltage of 25 kV was applied to the nozzle, and the barium titanate fiber precursor was collected on a grounded collector. The distance between the nozzle and the collector was 15 cm, and the temperature of the spinning space was 25° C. The barium titanate fiber precursor obtained by electrostatic spinning method is heated up to 1150° C. in the air at a temperature rise rate of 10° C./min, and is held at the calcination temperature of 1150° C. for 2 hours, and then by cooling the barium titanate fiber precursor to room temperature, a barium titanate fiber with an average fiber diameter of 0.3 μm was produced. Furthermore, by placing the obtained barium titanate fibers on a screen mesh with a mesh opening of 300 μm, filtering with a brush, and crushing, the barium titanate short fibers were obtained. The Ba/Ti ratio of the obtained barium titanate short fibers was 1.01, and the c/a ratio was 1.010, the aspect ratio was 5 (average fiber length: 1.5 μm, average fiber diameter: 0.3 μm).

### Preparation of Polymer Composite Piezoelectric Body

39 parts by weight of barium titanate short fibers prepared by the above-described method, 45 parts by weight of N,N-dimethylformamide, 5 parts by weight of copolymer (Kynar Ultraflex B produced by Arkema Inc.) of vinylidene fluoride and hexafluoropropylene, and 0.4 part by weight of polymeric dispersing agent (PB821 produced by Ajinomoto Fine-Techno Co., Inc.) were mixed to prepare a liquid resin composition. Then, using an applicator, by spreading the resin composition on an aluminum substrate with a thickness of 40 μm such that the thickness of the coating film was 600 μm, heating on a hot plate at 90° C., and evaporating N,N-dimethylformamide, a resin composition was formed in a film shape. The film-shaped resin composition was heat-pressed at a temperature of 200° C. and a pressure of 10 MPa for 3 minutes, and then, corona poling processing was performed. Corona poling processing was performed by applying a voltage of 7 kV for 100 seconds while heating the film-shaped resin composition to 60° C. The piezoelectric constant d₃₃ of the obtained polymer composite piezoelectric body was 106 pC/N. The relative dielectric constant of the polymer composite piezoelectric body was 67, the voltage output constant g₃₃ was 179 mVm/N, and the power generation performance index was 19.0×10⁻¹⁵ mVm/N².

### Example 2

The barium titanate short fibers and the polymer composite piezoelectric body were prepared in the same manner as that in Example 1, except that 22.07 parts by weight of titanium tetraisopropoxide were used. The obtained barium titanate short fibers have a Ba/Ti ratio of 1.03, a c/a ratio of 1.010, and an aspect ratio of 5 (average fiber length: 1.5 μm, average fiber diameter: 0.3 μm), and the piezoelectric constant d₃₃ of the polymer composite piezoelectric body was 91 pC/N. The relative dielectric constant of the polymer composite piezoelectric body was 59. the voltage output constant g₃₃ was 174 mVm/N, and the power generation performance index was 15.8×10⁻¹⁵ mVm/N².

### Example 3

The barium titanate short fibers and the polymer composite piezoelectric body were prepared in the same manner as that in Example 1, except that 20.52 parts by weight of barium carbonate, 5.4 parts by weight of polyvinylpyrrolidone, 54.6 parts by weight of propylene glycol monomethyl ether, and 29.27 parts by weight of titanium tetraisopropoxide were used. The obtained barium titanate short fibers have a Ba/Ti ratio of 1.01, a c/a ratio of 1.010, and an aspect ratio of 10 (average fiber length: 10 μm, average fiber diameter: 1.0 μm), and the piezoelectric constant d₃₃ of the polymer composite piezoelectric body was 102 pC/N. The relative dielectric constant of the polymer composite piezoelectric body was 56, the voltage output constant g₃₃ was 206 mVm/N, and the power generation performance index was 21.0×10⁻¹⁵ VCm/N².

### Example 4

The barium titanate short fibers and the polymer composite piezoelectric body were prepared in the same manner as that in Example 1, except that 23.68 parts by weight of barium carbonate, 6 parts by weight of polyvinylpyrrolidone, 54 parts by weight of propylene glycol monomethyl ether, and 33.77 parts by weight of titanium tetraisopropoxide were used. The obtained barium titanate short fibers have a Ba/Ti ratio of 1.01, a c/a ratio of 1.010, and an aspect ratio of 10 (average fiber length: 15 μm, average fiber diameter: 1.5 μm), and the piezoelectric constant d₃₃ of the polymer composite piezoelectric body was 101 pC/N. The relative dielectric constant of the polymer composite piezoelectric body was 66, the voltage output constant g₃₃ was 173 mVm/N, and the power generation performance index was 17.5×10⁻¹⁵ VCm/N².

### Example 5

The polymer composite piezoelectric body was prepared in the same manner as that in Example 3, except that 67 parts by weight of barium titanate short fibers and 0.7 part by weight of polymeric dispersing agent (PB821 produced by Ajinomoto Fine-Techno Co., Inc.) were used. The piezoelectric constant d₃₃ of the obtained polymer composite piezoelectric body was 105 pC/N, the relative dielectric constant was 46, the voltage output constant g₃₃ was 258 mVm/N, and the power generation performance index was 27.1×10⁻¹⁵ VCm/N².

### Comparative Example 1

The barium titanate short fibers and the polymer composite piezoelectric body were prepared in the same manner as that in Example 1, except that 22.74 parts by weight of titanium tetraisopropoxide were used. The obtained barium titanate short fibers have a Ba/Ti ratio of 1.00, a c/a ratio of 1.010, and an aspect ratio of 5 (average fiber length: 1.5 μm, average fiber diameter: 0.3 μm), and the piezoelectric constant d₃₃ of the polymer composite piezoelectric body was 74 pC/N. The relative dielectric constant of the polymer composite piezoelectric body was 79, the voltage output constant g₃₃ was 106 mVm/N, and the power generation performance index was 7.8×10⁻¹⁵ VC /N².

### Comparative Example 2

The barium titanate short fibers and the polymer composite piezoelectric body were prepared in the same manner as that in Example 1, except that 21.65 parts by weight of titanium tetraisopropoxide were used. The obtained barium titanate short fibers have a Ba/Ti ratio of 1.05, a c/a ratio of 1.010, and an aspect ratio of 5 (average fiber length: 1.5 μm, average fiber diameter: 0.3 μm), and the piezoelectric constant d₃₃ of the polymer composite piezoelectric body was 65 pC/N. The relative dielectric constant of the polymer composite piezoelectric body was 43, the voltage output constant g₃₃ was 171 mVm/N, and the power generation performance index was 11.1×10⁻¹⁵ VCm/N².

The average fiber diameter Ba/Ti ratio and aspect ratio of the barium titanate short fibers, and the piezoelectric constant d₃₃, relative dielectric constant, voltage output constant g₃₃ and power generation performance index of the polymer composite piezoelectric body in Examples 1 to 5 and Comparative Examples 1 and 2 are summarized in Table 1.

TABLE 1

| | Example | Example | Example | Example | Example | Comparative | Comparative |
|---|---|---|---|---|---|---|---|
| | 1 | 2 | 3 | 4 | 5 | Example 1 | Example 2 |
| Average fiber length [μm] | 0.3 | 0.3 | 1.0 | 1.5 | 1.0 | 0.3 | 0.3 |
| Ba/Ti ratio | 1.01 | 1.03 | 1.01 | 1.01 | 1.01 | 1.00 | 1.05 |
| Aspect ratio | 5 | 5 | 10 | 10 | 10 | 5 | 5 |
| Ratio of barium titanate fibers | 70 | 70 | 70 | 70 | 80 | 70 | 70 |
| to total amount of polymer | | | | | | | |
| and barium titanate fibers [% | | | | | | | |
| by volume] | | | | | | | |
| Piezoelectric constant d₃₃ | 106 | 91 | 102 | 101 | 105 | 74 | 65 |
| [pC/N] | | | | | | | |
| Relative dielectric constant | 67 | 59 | 56 | 66 | 46 | 79 | 43 |
| Voltage output constant g₃₃ | 179 | 174 | 206 | 173 | 258 | 106 | 171 |
| [mVm/N] | | | | | | | |
| Power generation | 19.0 | 15.8 | 21.0 | 17.5 | 27.1 | 7.8 | 11.1 |
| performance index [×10⁻¹⁶ | | | | | | | |
| VCm/N²] | | | | | | | |

As can be seen from Table 1, by using the barium titanate fibers with Ba/Ti ratios of from 1.01 to 1.04 as fillers in the polymer composite piezoelectric body, it was possible to obtain a polymer composite piezoelectric body with excellent piezoelectric properties.

### INDUSTRIAL APPLICABILITY

By using the barium titanate fibers of the present invention as fillers of the polymer composite piezoelectric body, it is possible to provide materials with high piezoelectric and dielectric properties and excellent flexibility, which can be suitably used for electroacoustic conversion equipment such as speakers and buzzers, actuators, tactile displays, sensors, and power generation devices.

1. A barium titanate fiber, wherein a molar ratio of barium atoms to titanium atoms (Ba/Ti ratio) falls within a range of 1.01 to 1.04.

2. The barium titanate fiber according to claim 1, which is a short fiber with an average fiber length of 0.5 to 1,000 μm.

3. The barium titanate fiber according to claim 1, which has an average fiber diameter in a range of 0.1 to 20 μm and an aspect ratio of 2 or greater.

4. A resin composition, containing the barium titanate fiber according to claim 1, and a polymer.

5. The resin composition according to claim 4, wherein a ratio of the barium titanate fiber to a total amount of the barium titanate fiber and the polymer is 10% to 90% by volume.

6. The resin composition according to claim 4, further containing 0.1% to 10% by weight of a dispersing agent and/or 0.1% to 10% by weight of a leveling agent with respect to the barium titanate fiber.

7. The resin composition according to claim 4, further containing a solvent.

8. The resin composition according to claim 4, which is used for producing a polymer composite piezoelectric body.

9. A polymer composite piezoelectric body containing the resin composition according to claim 4.

10. The polymer composite piezoelectric body according to claim 9, which has a voltage output constant g₃₃ of 150 mVm/N or greater.

11. A piezoelectric element, having an electrically conductive layer on one surface or both surfaces of the polymer composite piezoelectric body according to claim 9.

12. A method for producing a barium titanate fiber, comprising:
a process of preparing a spinning solution;
a process of preparing a barium titanate fiber precursor by electrostatically spinning the spinning solution; and
a process of calcining the precursor, wherein
in the process of preparing the spinning solution, the spinning solution is prepared such that a molar ratio of barium atoms to titanium atoms (Ba/Ti ratio) falls within a range of 1.01 to 1.04.

13. The method for producing a barium titanate fiber according to claim 12, further comprising a process of crushing the barium titanate fibers.

14. A method for producing a polymer composite piezoelectric body, comprising:
a process of obtaining a barium titanate fiber by the producing method according to claim 12;
a process of preparing a resin composition containing the barium titanate fiber, a polymer, and a solvent; and
a process of applying the resin composition to a support by a screen printing method.
